(19) United States
(12) Patent Application Publication
(10) Pub. No.: US 2013/0127010 A1
(43) Pub. Date: May 23, 2013

(54) INTEGRATED CIRCUIT INCLUDING A DIFFERENTIAL POWER AMPLIFIER WITH A SINGLE ENDED OUTPUT AND AN INTEGRATED BALUN

(71) Applicants: Alex Mostov, Rishon Le Zion (IL); Svetlana Kantor, Kfar-Saba (IL)

(72) Inventors: Anatoly Genik, Kfar Saba (IL); Alex Mostov, Rishon Le Zion (IL)

(73) Assignee: DSP Group Ltd., Herzeliya (IL)

(21) Appl. No.: 13/702,076

(22) PCT Filed: Jun. 9, 2010
(86) PCT No.: PCT/IL10/00459

§ 371 Date: Dec. 5, 2012

(51) Int. Cl. H01L 23/50; H01L 23/00

(52) U.S. Cl. CPC H01L 23/50; H01L 24/85
USPC 257/531; 438/106

(57) ABSTRACT

An integrated circuit, including, a die with an electronic circuit embedded thereon; wherein the electronic circuit includes a differential power amplifier and pads to electronically interface with the electronic circuit; a packaging encasing the die with contact pins to connect between the integrated circuit and external elements; wires connecting between the pads and the contact pins; a converter that includes capacitors and inductors to combine the outputs from the differential power amplifier to form a single ended output at one of the contact pins; wherein inherent inductance of some of the wires serve as the inductors of the converter.

### FIELD OF THE INVENTION

The present invention relates generally to an integrated circuit including a differential power amplifier with a single ended output embedded therein and more specifically wherein the integrated circuit package includes an integrated BALUN to provide the single ended output.

### BACKGROUND OF THE INVENTION

Many integrated circuit designers use differential amplifiers to improve the amplification quality in integrated circuits. The differential amplifiers allow stronger amplification without adding unnecessary noise to the integrated circuit.

One drawback is that differential amplifiers produce two output signals which have a phase shift between them so that they cannot be directly combined to form a single ended output without first bringing the two output signals into alignment. The alignment of the output signals requires use of a converter that converts balanced input to unbalanced output or vice versa, and is generally referred to as a BALUN. Use of a BALUN converter on the die of the integrated circuit would waste valuable space. One known type of converter uses transformers to align the output signals from the differential amplifier. Another type of converter uses a circuit including capacitors and inductors (e.g. a coil) to align the signals. In either case the converter wastes valuable space on the die of the integrated circuit unless the integrated circuit does not combine the outputs of the differential amplifier and leaves it to elements external to the integrated circuit to combine the signals. However, board designers generally prefer integrated circuits that provide the final result in contrast to integrated circuits that leave it up to the board designer to provide the required missing elements for designing an electronic device.

U.S. Pat. No. 7,592,872 to El Rai dated Sep. 22, 2009 describes a differential amplifier with a single ended output by forming a converter circuit in an integrated circuit.

### SUMMARY OF THE INVENTION

An aspect of an embodiment of the invention, relates to a differential power amplifier with a single ended output embedded in an integrated circuit. The output of the amplifier is converted using a BALUN converter that includes capacitors and inductors. The inductors are implemented by using the inherent inductance of the bond wires that connect between the integrated circuit die and the contact pins located in the encasement protecting the die that interface between the integrated circuit and external elements. Optionally, the capacitors of the converter are embedded in the die and connected to the outputs of the differential power amplifier.

In an exemplary embodiment of the invention, the inductance of the wires is controlled by their length and thickness. Optionally, the length of the wires is extended by offsetting the position of contact to the die or the position of the contact pin on the integrated circuit encasement. In an exemplary embodiment of the invention, the wires are not connected to the nearest contact pin, but rather to a contact pin that optimizes the level of inductance of the wires. In some embodiments of the invention, the die is offset from the center of the encasement and positioned closer to one side of the encasement to optimize the level of inductance of the wires. In some embodiments of the invention, additional wires are connected between the same point on the die and the same output pin to form a parallel inductor and thereby reduce the inductance to a specific pin. In some embodiments of the invention, each wire may have a different thickness to provide an optimal level of inductance.

There is thus provided according to an exemplary embodiment of the invention an integrated circuit, including:

A die with an electronic circuit embedded thereon; wherein the electronic circuit includes a differential power amplifier and pads to electronically interface with the electronic circuit;

A packaging encasing the die with contact pins to connect between the integrated circuit and external elements;

Wires connecting between the pads and the contact pins;

A converter that includes capacitors and inductors to combine the outputs from the differential power amplifier to form a single ended output at one of the contact pins; wherein inherent inductance of some of the wires serve as the inductors of the converter.

In an exemplary embodiment of the invention, the capacitors are embedded on the die between the differential power amplifier and the pads. Optionally, the die is positioned in the packaging so that the length of the wires will be optimized to provide inductance for the converter. In an exemplary embodiment of the invention, the position of some of the pads on the die or the contact pins on the packaging are offset to cause the wires connecting between them to be extended or shortened. Optionally, the designation of the contact pins used to connect to the differential power amplifier are selected so that the length of the wires will optimally provide inductance to the converter. In an exemplary embodiment of the invention, the thicknesses of the wires used to connect to the contacts of the differential power amplifier are selected to optimally provide inductance to the converter. Optionally, the trajectories of the wires used to connect to the contacts of the differential power amplifier are raised or lowered to optimally provide inductance to the converter. In an exemplary embodiment of the invention, multiple wires connect between a specific pad and pin of the contacts of the differential power amplifier to alter the inductance between the pad and the pin by forming multiple inductors in parallel.

There is further provided according to an exemplary embodiment of the invention, a method of converting the output of a differential power amplifier embedded on the die of an integrated circuit to a single ended output, comprising:

Positioning pads on the die to electronically interface with the electronic circuit on the die;

Forming a packaging to encase the die, wherein the packaging includes contact pins to connect the integrated circuit to external elements;

Connecting wires between the pads and contact pins serving as the contacts of the differential power amplifier;

Combining the outputs of the differential power amplifier using capacitors and inductors; wherein the inductors are provided by the wires connecting between the pads and the pins.

In an exemplary embodiment of the invention, the capacitors are embedded on the die between the differential power amplifier and the pads.

### BRIEF DESCRIPTION OF THE DRAWINGS

The present invention will be understood and better appreciated from the following detailed description taken in conjunction with the drawings. Identical structures, elements or parts, which appear in more than one figure, are generally labeled with the same or similar number in all the figures in which they appear, wherein:

FIG. 1A is a schematic illustration of an integrated circuit with a differential amplifier, according to an exemplary embodiment of the invention;

FIG. 1B is a schematic illustration of the electronic circuit layout of an integrated BALUN as implemented by FIG. 1A, according to an exemplary embodiment of the invention;

FIG. 2A is a schematic illustration of a cross sectional side view of an integrated circuit, according to an exemplary embodiment of the invention;

FIG. 2B is a schematic illustration of a top view of an integrated circuit, according to an exemplary embodiment of the invention; and

FIG. 3 is a schematic illustration of a top view of a variation of an integrated circuit, according to an exemplary embodiment of the invention.

### DETAILED DESCRIPTION

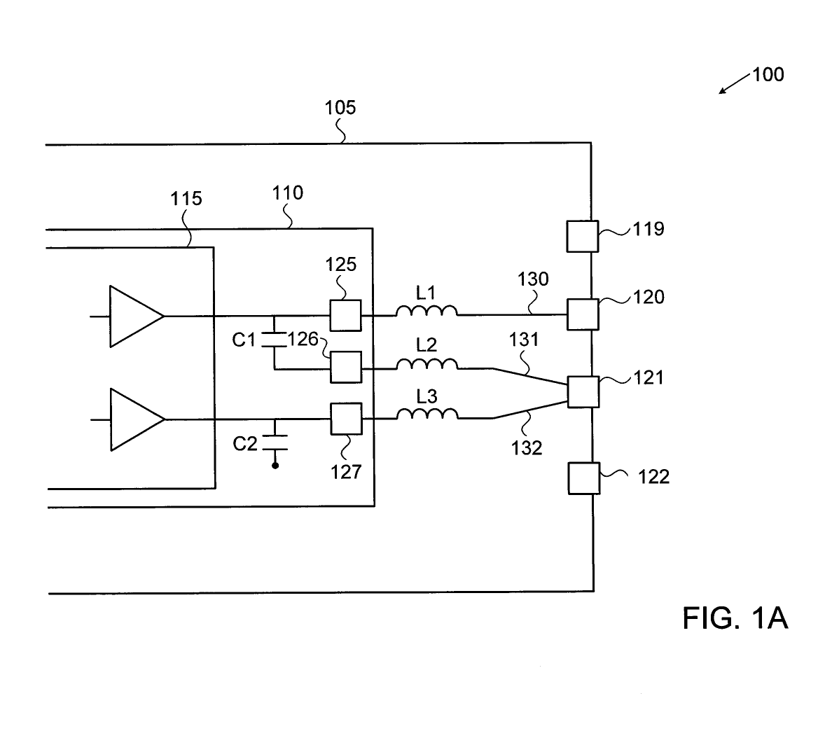

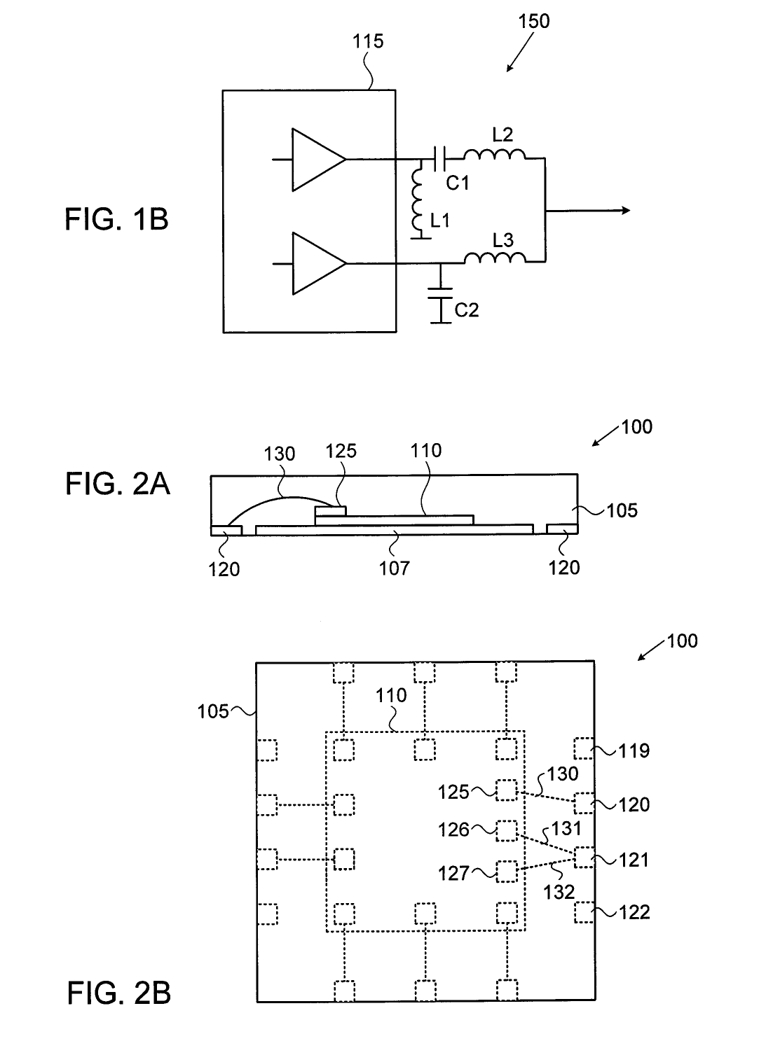

FIG. 1A is a schematic illustration of an integrated circuit 100 with a differential amplifier 115, and FIG. 1B is a schematic illustration of the electronic circuit layout of an integrated BALUN 150 as implemented by FIG. 1A, according to an exemplary embodiment of the invention. As shown in FIG. 1A integrated circuit 100 includes a die 110 with an electronic circuit embedded therein, the die including a differential amplifier 115. Optionally, integrated circuit 100 is placed on a metallic paddle 107 (shown in FIG. 2A) and encased by an integrated circuit (IC) package 105 (e.g. molded from plastic). In an exemplary embodiment of the invention, die 110 includes pads (e.g. 125, 126 and 127), which are positioned on the edges of die 110 to electrically connect between die 110 and contact pins (e.g. 120, 121 and 122) located on the bottom of IC package 105 for connecting the integrated circuit to external elements. Optionally, the contact pins (e.g. 120, 121 and 122) are originally part of paddle 107 and they are formed by cutting away an inner circumference from paddle 107 leaving the pins (e.g. 120, 121 and 122) isolated. Optionally, the connections between pads (e.g. 125, 126 and 127) and pins (e.g. 120, 121 and 122) are implemented by bond wires (e.g. 130, 131 and 132).

In an exemplary embodiment of the invention, the outputs of differential amplifier 115 are connected to BALUN 150, which is made up from capacitors and inductors as shown in the design of FIG. 1B. In an exemplary embodiment of the invention, the capacitors of BALUN 150 are implemented on die 110 whereas the inductors are implemented by exploiting the inherent inductance of the wires (130, 131, and 132) that connect between pads (125, 126, 127) and contact pins (120, 121, 122). Typically, wires (130, 131, 132) are thicker than the connections on die 110, for example with a thickness of about 20 μm for wires (130, 131, 132) relative to about 2 μm for connections internal to die 110. The extra thickness lowers resistance and reduces power loss. (130, 131, 132). The inductance is a function of the thickness and the length of the wire. The parasitic inductance generally interferes with the output of integrated circuits that function with high frequency/RF signals, whereas low frequency signals and DC signals are essentially not affected by the parasitic inductance. In an exemplary embodiment of the invention, inductor L1 of BALUN 150 is implemented by wire 130, inductor L2 is implemented by wire 131 and inductor L3 is implemented by wire 132. Wires 131 and 132 are both connected to pin 121 of integrated circuit 100 and wire 130 is connected to pin 120, which serves as a VCC input for BALUN 150.

FIG. 2A is a schematic illustration of a side cross sectional view of integrated circuit 100 and FIG. 2B is a schematic illustration of a top view of integrated circuit 100, according to an exemplary embodiment of the invention. In some embodiments of the invention the position of pins 120 and 121 may be offset relative to pads 125, 126 and 127 so that longer or shorter connecting wires 130, 131 and 132 will be used to increase or reduce the inductance of inductors L1, L2 and L3 as required for the design of BALUN 150. Alternatively or additionally, pads 125, 126 and 127 may be intentionally wired to pins that are further away (e.g. 119 and 122) so that the length of the wires will be increased. Optionally, thicker or thinner wires may be used for one or more of the connecting wires (130, 131, 132) to increase or reduce the inductance of the wires. In some embodiments of the invention, the trajectory of wires (130, 131, 132) (e.g. as shown in FIG. 2A for wire 130) is raised or lowered so that wires (130, 131, 132) will be longer or shorter thus increasing or decreasing their inductance.

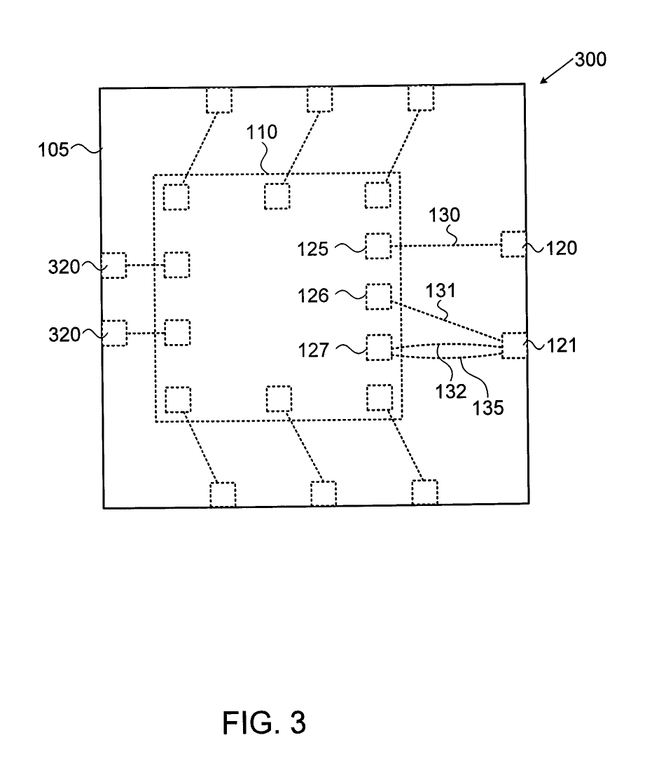

FIG. 3 is a schematic illustration of a top view of a variation of integrated circuit 100, according to an exemplary embodiment of the invention. In an exemplary embodiment of the invention, an integrated circuit 300 is designed wherein die 110 is offset from the center of IC package 105, for example positioned more to one side than the other. Optionally, this allows two benefits:

1. Reducing the parasitic inductance for the outputs 320 of the integrated circuit on the side that does not include a differential amplifier 115;

2. Increasing the inductance of wires 130, 131, 132 so that the positioning of the die 110 can be used to increase or reduce the inductance to a desired value.

In some embodiments of the invention, one or more of wires 130, 131 and 132 may be implemented by multiple wires in parallel (e.g. 132 and 135) to control the total inductance between the pads (125, 126, 127) and the contact pins (120, 121, 122). In FIG. 3, wire 132 is provided with a parallel wire 135 to reduce the total inductance between pad 127 and pin 121.

It should be appreciated that the above described methods and apparatus may be varied in many ways, including omitting or adding steps, changing the order of steps and the type of devices used. It should be appreciated that different features may be combined in different ways. In particular, not all the features shown above in a particular embodiment are necessary in every embodiment of the invention. Further combinations of the above features are also considered to be within the scope of some embodiments of the invention.

It will be appreciated by persons skilled in the art that the present invention is not limited to what has been particularly shown and described hereinabove. Rather the scope of the present invention is defined only by the claims, which follow.

1. An integrated circuit, comprising:
a die with an electronic circuit embedded thereon; wherein the electronic circuit includes a differential power amplifier that produces two output signals with a phase shift between them and pads to electronically interface with the electronic circuit;
a packaging encasing the die with contact pins to connect between the integrated circuit and external elements;
wires connecting between the pads and the contact pins;
a converter that includes capacitors and inductors to combine the output signals of the differential power amplifier to form a single ended output signal at one of the contact pins; wherein inherent inductance of some of the wires serve as the inductors of the converter.

2. An integrated circuit according to claim 1, wherein the capacitors are embedded on the die between the differential power amplifier and the pads.

3. An integrated circuit according to claim 1, wherein the die is positioned in the packaging so that the length of the wires will be optimized to provide inductance for the converter.

4. An integrated circuit according to claim 1, wherein the position of some of the pads on the die or the contact pins on the packaging are offset to cause the wires connecting between them to be extended or shortened.

5. An integrated circuit according to claim 1, wherein the designation of the contact pins used to connect to the differential power amplifier are selected so that the length of the wires will optimally provide inductance to the converter.

6. An integrated circuit according to claim 1, wherein the thicknesses of the wires used to connect to the contacts of the differential power amplifier are selected to optimally provide inductance to the converter.

7. An integrated circuit according to claim 1, wherein the trajectories of the wires used to connect to the contacts of the differential power amplifier are raised or lowered to optimally provide inductance to the converter.

8. An integrated circuit according to claim 1, wherein multiple wires connect between a specific pad and pin of the contacts of the differential power amplifier to alter the inductance between the pad and the pin by forming multiple inductors in parallel.

9. A method of converting the output of a differential power amplifier that produces two output signals with a phase shift between them embedded on the die of an integrated circuit to a single ended output signal, comprising:
positioning pads on the die to electronically interface with the electronic circuit on the die;
forming a packaging to encase the die, wherein the packaging includes contact pins to connect the integrated circuit to external elements;
connecting wires between the pads and contact pins serving as the contacts of the differential power amplifier;
combining the output signals of the differential power amplifier using capacitors and inductors; wherein the inductors are provided by the wires connecting between the pads and the pins.

10. A method according to claim 9, wherein the capacitors are embedded on the die between the differential power amplifier and the pads.
